(19) United States
(12) Patent Application Publication
(10) Pub. No.: US 2012/0181693 A1
(43) Pub. Date: Jul. 19, 2012

(54) SEMICONDUCTOR DEVICE AND METHOD OF FORMING THE SAME

(75) Inventors: Jeeyong Kim, Hwaseong-si (KR); Jong-Hyun Park, Seoul (KR); Jin-Kyu Kang, Seoul (KR); Joonhee Lee, Seongnam-si (KR)

(73) Assignee: SAMSUNG ELECTRONICS CO., LTD., Suwon-si (KR)

(21) Appl. No.: 13/241,741

(22) Filed: Sep. 23, 2011

(30) Foreign Application Priority Data
Jan. 17, 2011 (KR) 10-2011-0004628

(51) Int. Cl. H01L 23/532

(52) U.S. Cl. 257/751; 257/E23.155

(57) ABSTRACT

A semiconductor device may include an upper interconnection on a substrate and an anti-reflection pattern disposed on the upper interconnection. The anti-reflection pattern may include a compound including a metal, carbon and nitrogen.

### CROSS-REFERENCE TO RELATED APPLICATIONS

This U.S. non-provisional patent application claims priority under 35 U.S.C. §119 to Korean Patent Application No. 10-2011-0004628, filed on Jan. 17, 2011, the entire contents of which are hereby incorporated by reference.

### BACKGROUND

Embodiments of the present inventive concept herein relate to semiconductor devices and methods of forming the same, and more particularly, to a semiconductor device including an anti-reflection pattern disposed on an interconnection and a method of forming the same.

Semiconductor devices have been in the limelight as an important element in the electronics industry because of their characteristics, such as a capability for miniaturization, multi-function properties and/or low manufacturing cost.

Semiconductor devices may be classified by application into the following groups; (a) semiconductor devices storing logic data, (b) semiconductor logic devices that process logic data, and (c) hybrid semiconductor devices including memory elements and logic elements.

As electronic devices become high speed and operate with low power consumption, semiconductor devices incorporated into the electronic devices can offer advantages if they likewise have a high operation speed and/or a low operation voltage. To meet these targets, semiconductor devices are being highly integrated; and as semiconductor devices are more highly integrated, reliability of these semiconductor devices may deteriorate. However, as the electronics industry is increasingly highly developed, high reliability of semiconductor devices is increasingly advantageous. Thus, many studies for improving the reliability of semiconductor devices are being performed.

### SUMMARY

Embodiments of the inventive concept may include a semiconductor device. The semiconductor device may include an upper interconnection on a substrate and an anti-reflection pattern disposed on the upper interconnection. The anti-reflection pattern may include a compound including metal, carbon and nitrogen.

Embodiments of the inventive concept may also include a method of forming a semiconductor device. The method may include forming an electrically conductive film and an anti-reflection film on a substrate and forming an upper interconnection and an anti-reflection pattern by patterning the conductive film and the anti-reflection film. The anti-reflection film is formed by a chemical vapor deposition process using a source gas including a metal, carbon and nitrogen.

In various embodiments, the compound included in the anti-reflection pattern may have a carbon content of 5-40 atomic %, and the compound included in the anti-reflection pattern may further comprise oxygen.

In various embodiments, the upper interconnection and the anti-reflection pattern may be directly in contact with each other; and the semiconductor device may further include the following: a mold dielectric film and an interlayer dielectric film that are sequentially stacked between the substrate and the upper interconnection; a lower interconnection in the mold dielectric film; a capping film (comprising, e.g., a nitride) on the mold dielectric film; and a contact plug penetrating the interlayer dielectric film and the capping film between the upper interconnection and the lower interconnection and electrically connecting the upper interconnection and the lower interconnection.

In various embodiments, a mobile element in the semiconductor device has a diffusion coefficient in the compound included in the anti-reflection pattern that is greater than the diffusion coefficient of the mobile element in the capping film and/or greater than the diffusion coefficient of the mobile element in PVD-metal nitride.

In various embodiments, the compound included in the anti-reflection pattern may be selected from at least one of titanium carbon nitride and titanium carbon oxygen nitride, and/or the compound included in the anti-reflection pattern may have a density lower than the density of PVD-metal nitride.

In various embodiments, the upper interconnection may include an electrically conductive line and a barrier pattern lining the electrically conductive line. The electrically conductive line may include at least one of a doped semiconductor, a metal, and a conductive metal-semiconductor compound; and the barrier pattern may include at least one of a metal nitride and a transition metal.

In various embodiments, the upper interconnection and the anti-reflection pattern may be formed by a dry etching process performed in one chamber.

In various embodiments, the method includes, before forming the upper interconnection: forming a mold dielectric film including a trench extending in a first direction on the substrate; forming a lower interconnection in the trench; forming a capping film on the mold dielectric film; forming an interlayer dielectric film on the mold dielectric film; and forming a contact plug penetrating the interlayer dielectric film and the capping film and electrically connecting the upper interconnection and the lower interconnection.

In various embodiments, the method further includes forming a protective film covering the upper interconnection and the anti-reflection pattern on the interlayer dielectric film.

In additional embodiments, the semiconductor device includes the following:

a substrate;

a first layer on the substrate, the first layer including a mold dielectric film that defines a trench and a lower interconnection mounted in the trench defined by the mold dielectric film, wherein the lower interconnection includes a first electrically conductive line and a first barrier pattern between the first electrically conductive line and both the mold dielectric film and the substrate;

a second layer on the first layer on an opposite side of the first layer from the substrate, the second layer including (a) a capping film on the mold dielectric film, (b) an interlayer dielectric film on the capping film, wherein the interlayer dielectric film defines a trench, and (c) a contact plug in the trench defined by the interlayer dielectric film and on the lower interconnection, wherein the contact plug includes a contact conductive pattern and a contact barrier pattern between the contact conductive pattern and the capping film;

a third layer on the second layer on an opposite side of the second layer from the first layer, the third layer including an upper interconnection including a second electrically conductive line and a second barrier pattern between the second electrically conductive line and the second layer; and

an anti-reflection pattern on the second electrically conductive line on an opposite side of the electrically conductive line from the second barrier pattern, wherein the anti-reflection pattern comprises a compound including a metal, carbon and nitrogen.

In various embodiments, the capping film may have a composition in which hydrogen has a diffusion coefficient that is lower than the diffusion coefficient of hydrogen in the anti-reflection pattern; the substrate may comprise at least one of silicon and germanium; the mold dielectric film and the interlayer dielectric film may comprise at least one selected from an oxide, a nitride and an oxynitride; the first and second electrically conductive lines as well as the contact conductive pattern may comprise at least one selected from a doped semiconductor, a metal and a conductive metal-semiconductor compound; the first and second barrier patterns as well as the contact barrier pattern may comprise at least one selected from a metal nitride and a transition metal; and the capping film may comprise a nitride.

### BRIEF DESCRIPTION OF THE FIGURES

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1A is a top-plan view of a semiconductor device in accordance with an embodiment of the inventive concept.

FIG. 1B is a cross-sectional view taken along the line I-I′ of FIG. 1A.

FIG. 1C is a cross-sectional view taken along the line II-II′ of FIG. 1A.

FIGS. 2A, 3A, 4A, 5A, 6A, 7A and 8A are top-plan views of the embodiment of a semiconductor device and are presented to facilitate explaining a method for forming the device in accordance with an embodiment of the inventive concept.

FIGS. 2B, 3B, 4B, 5B, 6B, 7B and 8B are cross-sectional views taken along the line I-I′ of FIGS. 2A, 3A, 4A, 5A, 6A, 7A and 8A, respectively, and are presented to facilitate explaining a method of forming the semiconductor device in accordance with an embodiment of the inventive concept.

FIGS. 2C, 3C, 4C, 5C, 6C, 7C and 8C are cross-sectional views taken along the line II-II′ of FIGS. 2A, 3A, 4A, 5A, 6A, 7A and 8A, respectively, and are presented to facilitate explaining a method of forming the semiconductor device in accordance with an embodiment of the inventive concept.

FIG. 9 is a block diagram illustrating an example of an electronic system including a semiconductor device in accordance with exemplary embodiments of the inventive concept.

FIG. 10 is a block diagram illustrating an example of a memory card including a semiconductor device in accordance with exemplary embodiments of the inventive concept.

### DETAILED DESCRIPTION OF THE EMBODIMENTS

Preferred embodiments of the inventive concept will be described below in more detail with reference to the accompanying drawings. The embodiments of the inventive concept may, however, be embodied in different forms and should not be construed as being limited to the embodiments set forth herein. Rather, these embodiments are provided so that this disclosure will be thorough and complete and will fully convey the scope of the inventive concept to those skilled in the art. Like numbers refer to like elements throughout.

In the drawings, the thickness of layers and regions are exaggerated for clarity. It will be further understood that the terms “comprises” and/or “comprising, ” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. It will also be understood that when an element such as a layer, region or substrate is referred to as being “on” or “onto” another element, it may lie directly on the other element or intervening elements or intervening layers may also be present.

Spatially relative terms, such as “above,” “below,” “left,” “right,” “in front,” “behind,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

It will be understood that, although the terms first, second, etc., may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

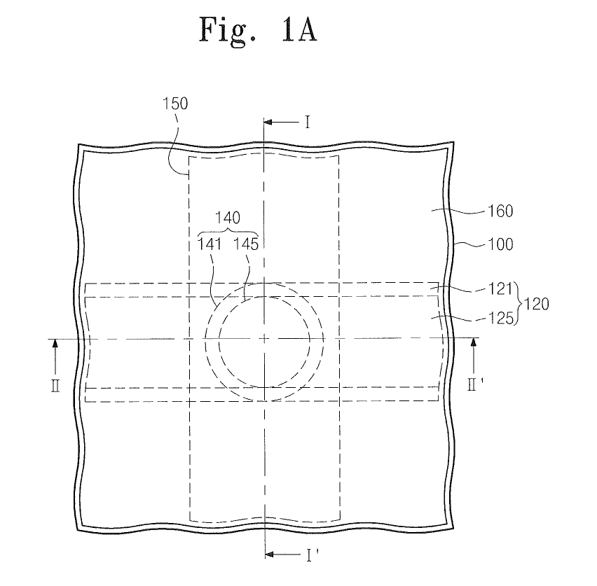

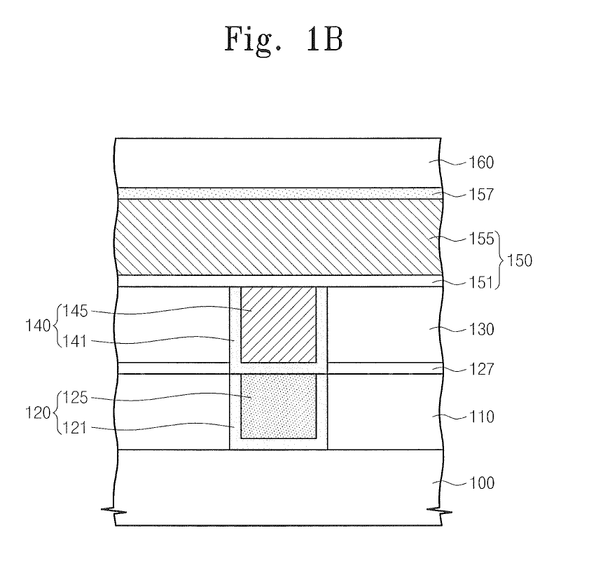

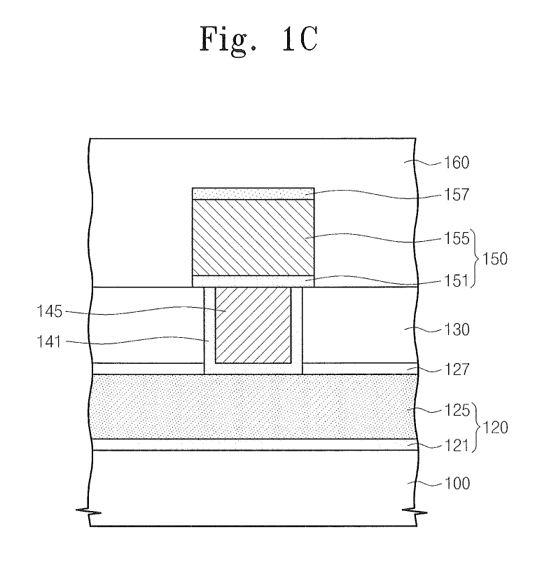

Hereinafter, a semiconductor device in accordance with an embodiment is described with reference to the drawings. FIG. 1A is a top-plan view for explaining a semiconductor device in accordance with an embodiment of the inventive concept. FIG. 1B is a cross-sectional view taken along the line I-I′ of FIG. 1A. FIG. 1C is a cross-sectional view taken along the line II-II′ of FIG. 1A.

Referring to FIGS. 1A through 1C, a first layer including a mold dielectric film 110 and a second layer including an interlayer dielectric film 130 may be disposed on a substrate 100. The mold dielectric film 110 and the interlayer dielectric film 130 may include at least one of an oxide, a nitride or an oxynitride. According to an embodiment, the mold dielectric film 110 and the interlayer dielectric film 130 may include the same material.

The substrate 100 may include at least one of silicon and germanium. According to an embodiment, the substrate 100 may include components constituting a semiconductor device. For example, the components may include at least one of a transistor, a diode, a capacitor and a resistor.

A lower interconnection 120 extending in a first direction (orthogonal to the plane of the page in the illustrated orientation) may be disposed in the mold dielectric film 110. The lower interconnection 120 may include a first barrier pattern 121 and a first conductive line 125. The first direction may be parallel to an x axis. The first conductive line 125 may have a line shape extending in the first direction in plan view. According to an embodiment, the first barrier pattern 121 may be disposed between the mold dielectric film 110 and the first conductive line 125. The first barrier pattern 121 may cover both sidewalls of the first conductive line 125 and a bottom surface of the first conductive line 125. A cross section of the first barrier pattern 121 may have a U character shape. In this case, the mold dielectric film 110 and the first conductive line 125 may be spaced apart from each other by the first barrier pattern 121. The first barrier pattern 121 may include a metal nitride (e.g., titanium nitride, tungsten nitride or tantalum nitride) or a transition metal (e.g., titanium, tantalum, etc.). The first conductive line 125 may include at least one selected from a doped semiconductor (e.g., doped silicon), a metal (e.g., tungsten, aluminum, copper, etc.) and a conductive metal-semiconductor compound (e.g., a metal silicide).

According to an embodiment, the lower interconnection 120 may be electrically connected to at least one of the components constituting a semiconductor device that can be included in the substrate 100.

A capping film 127 may be disposed between the lower interconnection 120 and the interlayer dielectric film 130. For example, the capping film 127 may include silicon nitride. According to an embodiment, the capping film 127 may laterally extend to cover an entire top surface of the mold dielectric film 110. In this case, an extension portion of the capping film 127 may be disposed between the mold dielectric film 110 and the interlayer dielectric film 130. The capping film 127 may minimize diffusion of conductive particles included in the lower interconnection 120 to outside the lower interconnection 120.

An upper interconnection 150 extending in a second direction crossing the first direction (and extending horizontally in the orientation shown) may be disposed on the interlayer dielectric film 130 to form a third layer on the substrate 100. According to an embodiment, the second direction may be parallel to a y axis, which is orthogonal to the x axis. The upper interconnection 150 may include a second barrier pattern 151 and a second conductive line 155. The second conductive line 155 and the second barrier pattern 151 may be a line shape extending in the second direction in plan view. The second barrier pattern 151 may be disposed between the interlayer dielectric film 130 and the second conductive line 155. Thus, the interlayer dielectric film 130 and the second conductive line 155 may be spaced apart from each other by the second barrier pattern 151. According to an embodiment, a sidewall of the second barrier pattern 151 may be aligned with a sidewall of the second conductive line 155.

The second barrier pattern 151 may include a metal nitride (e.g., titanium nitride, tungsten nitride or tantalum nitride) or a transition metal (e.g., titanium, tantalum, etc.). The second conductive line 155 may include at least one selected from a doped semiconductor (e.g., doped silicon), a metal (e.g., tungsten, aluminum, copper, etc.) and a conductive metal-semiconductor compound (e.g., a metal silicide).

A contact plug 140 penetrating the interlayer dielectric film 130 and the capping film 127 may be disposed between the lower interconnection 120 and the upper interconnection 150. The contact plug 140 may electrically connect the lower interconnection 120 and the upper interconnection 150.

The contact plug 140 may include a contact barrier pattern 141 and a contact conductive pattern 145. According to an embodiment, a side surface and a bottom surface of the contact conductive pattern 145 may be covered with the contact barrier pattern 141; and the contact plug 140 may have a cylindrical shape.

The contact barrier pattern 141 may include a metal nitride (e.g., titanium nitride, tungsten nitride or tantalum nitride) or a transition metal (e.g., titanium, tantalum, etc.). The contact conductive pattern 145 may include at least one selected from a doped semiconductor (e.g., doped silicon), a metal (e.g., tungsten, aluminum, copper, etc.) and a conductive metal-semiconductor compound (e.g., a metal silicide).

An anti-reflection pattern 157 may be disposed on the upper interconnection 150. According to an embodiment, the anti-reflection pattern 157 may completely overlap a top surface of the upper interconnection 150. Sidewalls of the anti-reflection pattern 157 and the upper interconnection 150 may be aligned with each other.

According to an embodiment, the anti-reflection pattern 157 may be directly in contact with the upper interconnection 150.

The anti-reflection pattern 157 may include a compound including a metal, carbon and nitrogen. For example, a metal included in the compound may be titanium. According to an embodiment, a carbon content of the compound included in the anti-reflection pattern 157 may be 5-40 atomic %.

According to an embodiment, the density of the compound included in the anti-reflection pattern 157 may be lower than the density of PVD-metal nitride (e.g., in the contact barrier pattern 141). For example, the metal included in the compound may be titanium, and the PVD-metal nitride may be titanium nitride. Density, here, is expressed as mass per unit volume.

According to an embodiment, the compound may optionally include oxygen. For example, the compound may be titanium-carbon-nitride (TiCN) or titanium-carbon-oxygen-nitride (TiCON).

According to an embodiment, a diffusion coefficient of a mobile element in the anti-reflection pattern 157 may be greater than a diffusion coefficient of the mobile element in the capping film 127. Also, a diffusion coefficient of a mobile element in a compound included in the anti-reflection pattern 157 may be greater than a diffusion coefficient of the mobile element in the PVD-metal nitride. The mobile element may include elements that can freely move in a film. For example, the mobile element may be hydrogen.

In an embodiment of the semiconductor device, the anti-reflection pattern 157 disposed on the upper interconnection 150 may be formed of a compound including metal, carbon and nitrogen. The compound included in the anti-reflection pattern 157 may be a porous material. Accordingly, in a process for forming a semiconductor device, a mobile element that passed through components constituting a semiconductor device may be easily emitted to the outside through the anti-reflection pattern 157.

Also, the diffusion coefficient of a mobile element in the anti-reflection pattern 157 may be greater than the diffusion coefficient of the mobile element in the capping film 127. In the case that mobile elements existing in components constituting a semiconductor device are prevented from emitting to the outside by the capping film 127, the mobile elements diffuse through the contact plug 140 and the upper interconnection 150 and then are easily emitted to the outside of the semiconductor device through the anti-reflection pattern 157. Thus, the problems that may be caused by the mobile elements in the semiconductor device may be minimized.

A protective film 160 covering the upper interconnection 150 and the anti-reflection pattern 157 may be disposed on the interlayer dielectric film 130. The protective film 160 may include at least one of an oxide, a nitride and an oxynitride.

According to an embodiment of the inventive concept, the anti-reflection pattern 157 disposed on the upper interconnection 150 may be formed of a compound including a metal, carbon and nitrogen. The compound may be a porous material having a high diffusion coefficient for mobile elements. Thus, mobile elements existing in components constituting the semiconductor device may be easily emitted to the outside through the anti-reflection pattern 157. Consequently, problems that may be caused by the mobile elements in the semiconductor device may be minimized; and a semiconductor device may be produced having improved reliability.

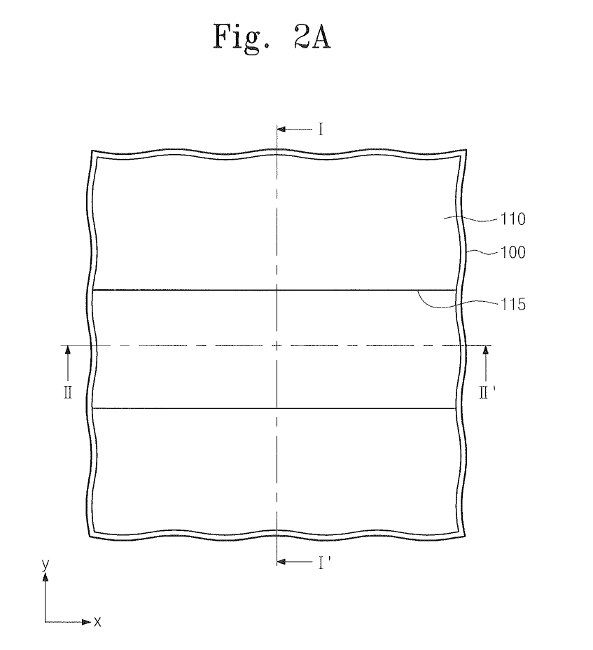

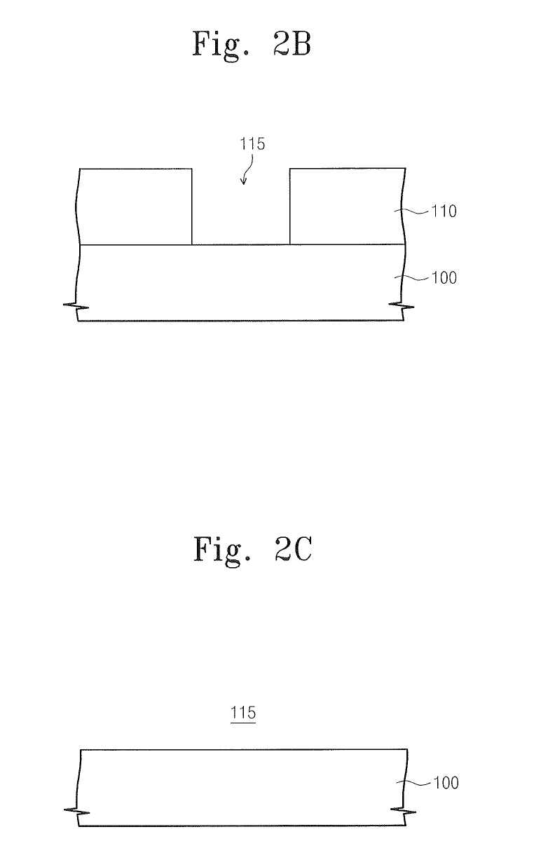

Hereinafter, a semiconductor device in accordance with an embodiment of the inventive concept is described with reference to the drawings. FIGS. 2A , 3A, 4A, 5A, 6A, 7A and 8A are top-plan views for explaining a method of forming a semiconductor device in accordance with an embodiment of the inventive concept. FIGS. 2B , 3B, 4B, 5B, 6B, 7B and 8B are cross-sectional views taken along the line I-I′ of FIGS. 2A, 3A, 4A, 5A, 6A, 7A and 8A. FIGS. 2C, 3C, 4C, 5C, 6C, 7C and 8C are cross-sectional views taken along the line II-II′ of FIGS. 2A, 3A, 4A, 5A, 6A, 7A and 8A.

Referring to FIGS. 2A, 2B and 2C, a mold dielectric film 110 may be formed on a substrate 100. The mold dielectric film 110 may be formed by at least one of a chemical vapor deposition (CVD) process, a physical vapor deposition (PVD) process and an atomic layer deposition (ALD) process. The dielectric film 110 may include at least one of an oxide, a nitride and an oxynitride.

The substrate 100 may include at least one of silicon and germanium. According to an embodiment, the substrate 100 may include components constituting a semiconductor device. For example, the components may include at least one of a transistor, a diode, a capacitor and a resistor.

A trench 115 extending in a first direction (orthogonal to the plane of the page in the orientation shown) may be formed in the mold dielectric film 110. According to an embodiment, the first direction may be parallel to an x axis. The trench 115 may be formed by etching a part of the mold dielectric film 110. According to an embodiment, the trench 115 may expose at least a part of the substrate 100. The trench may also expose a part of compounds constituting the semiconductor device.

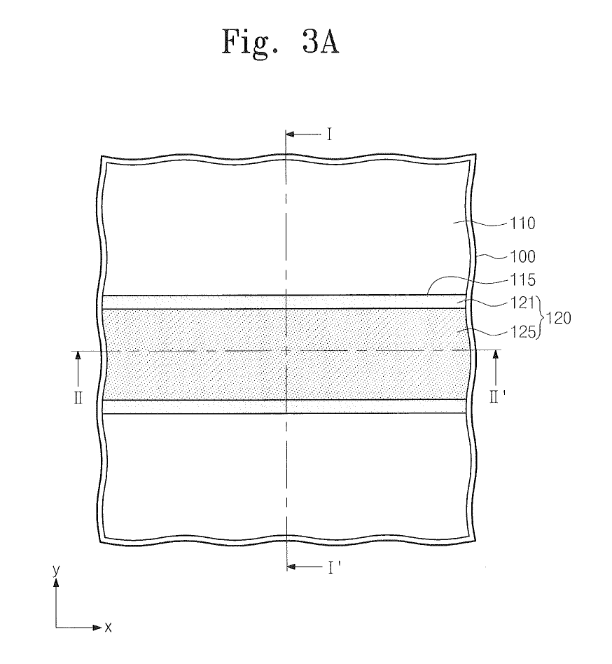

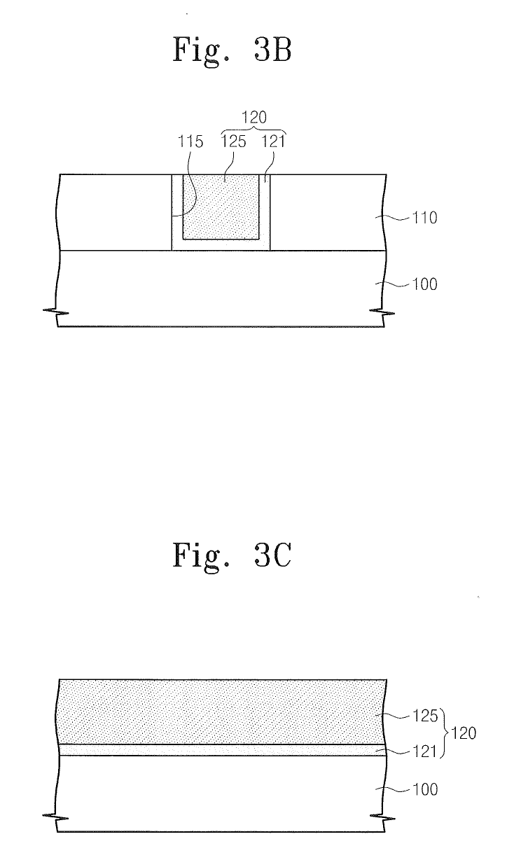

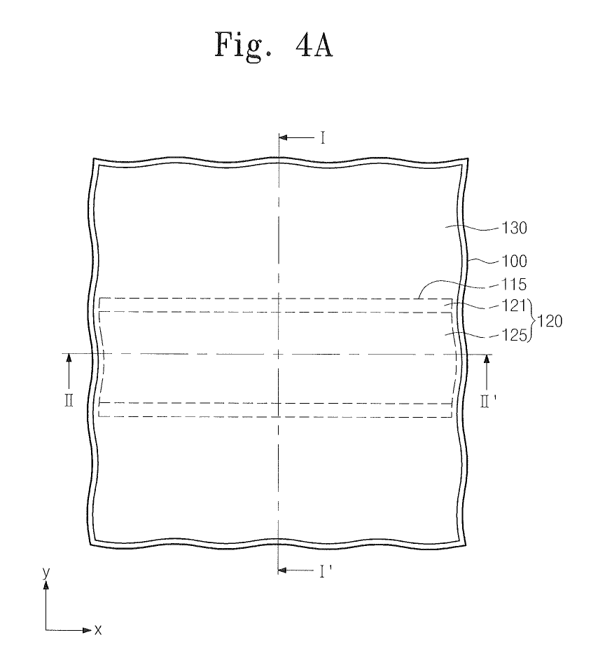

Referring to FIGS. 3A, 3B and 3C, a lower interconnection 120 may be formed in the trench 115. The lower interconnection 120 may be formed in a line shape extending in the first direction. According to an embodiment, the lower interconnection 120 may include a first barrier pattern 121 and a first electrically conductive line 125. The first barrier pattern 121 may include a metal nitride (e.g., titanium nitride, tungsten nitride or tantalum nitride) or a transition metal (e.g., titanium, tantalum, etc.). The first conductive line 125 may include at least one selected from a doped semiconductor (e.g., doped silicon), a metal (e.g., tungsten, aluminum, copper, etc.) and a conductive metal-semiconductor compound (e.g., a metal silicide).

The lower interconnection 120 may be formed by conformally forming a first barrier film on the mold dielectric film 110, forming a first electrically conductive film [e.g., formed of a doped semiconductor (e.g., doped silicon), a metal (e.g., tungsten, aluminum, copper, etc.) or a conductive metal-semiconductor compound (e.g., a metal silicide)] filling the inside of the trench 115 on the mold dielectric film 110 and etching the first barrier film and the first conductive film until a top surface of the mold dielectric film is exposed. The first barrier film may be formed by at least one of a chemical vapor deposition (CVD) process, a physical vapor deposition (PVD) process and an atomic layer deposition (ALD) process. The first conductive film may be formed by at least one of a chemical vapor deposition (CVD) process, a physical vapor deposition (PVD) process, an atomic layer deposition (ALD) process and a plating process. Etching the first barrier film and the first conductive film may be performed by a dry etching process or by a chemical mechanical planarization (CMP) process.

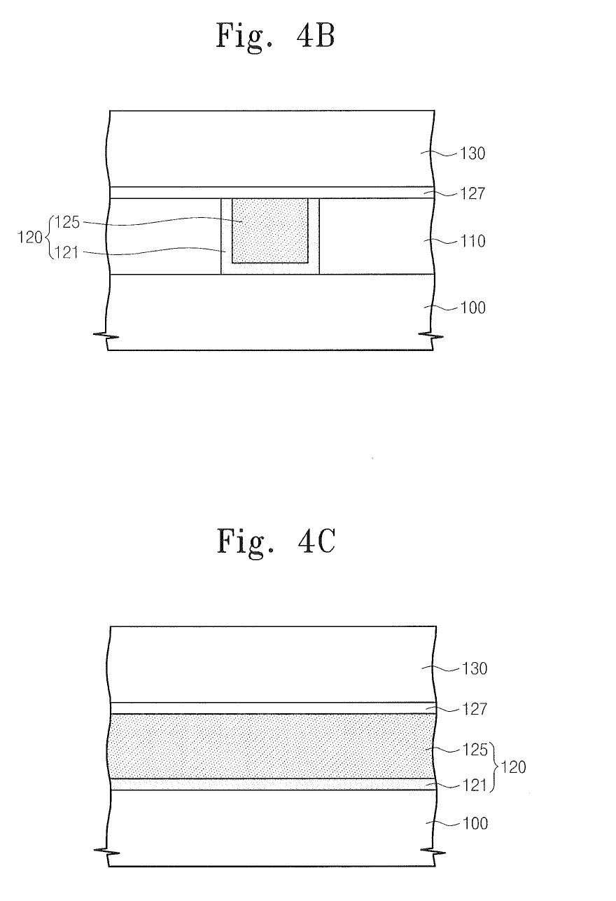

Referring to FIGS. 4A, 4B and 4C, a capping film 127 may be formed on the substrate 100 including the lower interconnection 120. According to an embodiment, the capping film 127 may be formed on an entire surface of the substrate 100 using a chemical vapor deposition (CVD) process. The capping film 127 may also be limitedly formed on the lower interconnection 120 by a selective forming method. In this case, the capping film 127 may be formed of a conductive metal nitride.

According to an embodiment, the capping film 127 may include a material that can prevent conductive particles included in the lower interconnection 120 from diffusing to the outside of the lower interconnection 120. For example, the capping film 127 may include a nitride. The capping film 127 may be formed by at least one of a chemical vapor deposition (CVD) process, a physical vapor deposition (PVD) process and an atomic layer deposition (ALD) process.

An interlayer dielectric film 130 may be formed on the mold dielectric film 110. The interlayer dielectric film 130 may be formed by at least one of a chemical vapor deposition (CVD) process, a physical vapor deposition (PVD) process and an atomic layer deposition (ALD) process. The interlayer dielectric film 130 may include at least one of an oxide, a nitride and an oxynitride. In the case that the capping film 127 covers an entire top surface of the mold dielectric film 110, the interlayer dielectric film 130 may be formed on the capping film 127 so that the capping film 127 is disposed between the mold dielectric film 110 and the interlayer dielectric film 130.

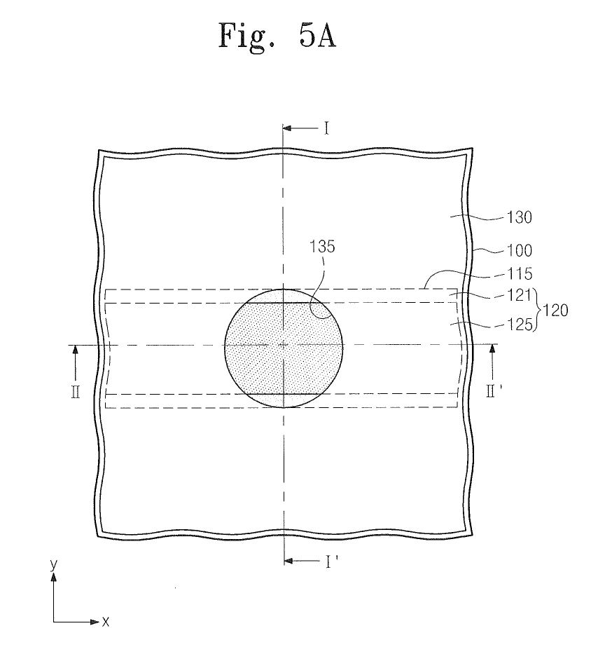

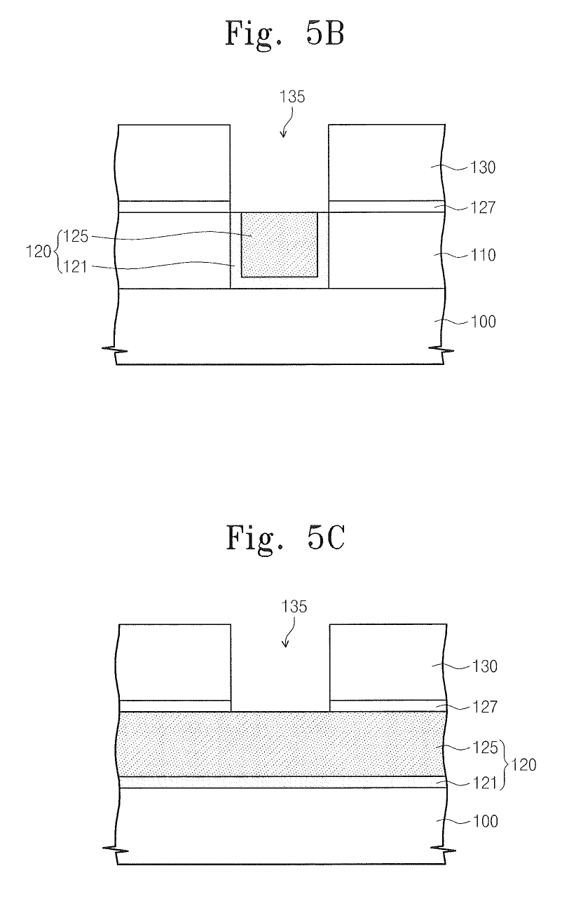

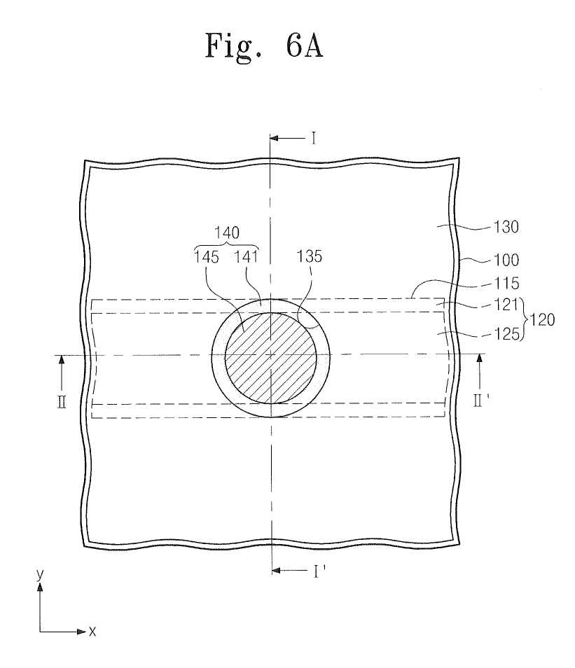

Referring to FIGS. 5A, 5B and 5C, a hole 135 penetrating the interlayer dielectric film 130 and the capping film 127 may be formed. According to an embodiment, the hole 135 may expose at least a part of top surface of the lower interconnection 120. The hole 135 may be formed by etching a part of the interlayer dielectric film 130 and the capping film 127.

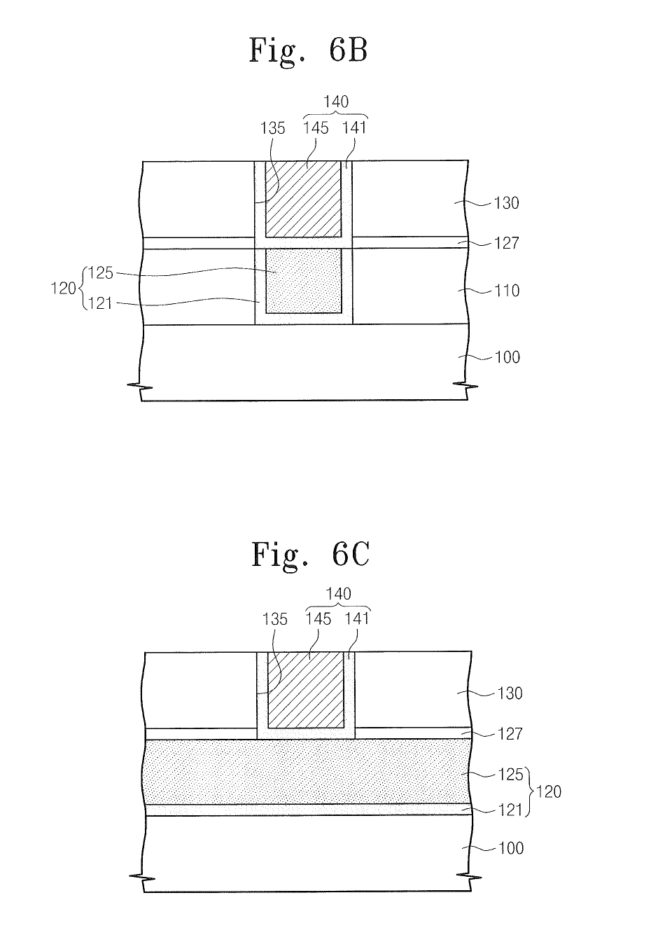

Referring to FIGS. 6A, 6B and 6C, a contact plug 140 may be formed in the hole 135. The contact plug 140 may include a contact barrier pattern 141 and a contact conductive pattern 145. Forming the contact plug 140 may include conformally forming a contact barrier film on the interlayer dielectric film 130, forming a contact conductive film filling the hole 135 on the interlayer dielectric film 130 and etching the contact barrier film and the contact conductive film until a top surface of the interlayer dielectric film 130 is exposed. The contact barrier film may be formed by at least one of a chemical vapor deposition (CVD) process, a physical vapor deposition (PVD) process and an atomic layer deposition (ALD) process. The contact conductive film may be formed by at least one of a chemical vapor deposition (CVD) process, a physical vapor deposition (PVD) process, an atomic layer deposition (ALD) process and a plating process. Etching the contact barrier film and the contact conductive film may be performed by a dry etching process or a chemical mechanical planarization (CMP) process.

The contact barrier pattern 141 may include a metal nitride (e.g., titanium nitride, tungsten nitride or tantalum nitride) or a transition metal (e.g., titanium, tantalum, etc.). The contact conductive pattern 145 may include at least one selected from a doped semiconductor (e.g., doped silicon), a metal (e.g., tungsten, aluminum, copper, etc.) and a conductive metal-semiconductor compound (e.g., a metal silicide).

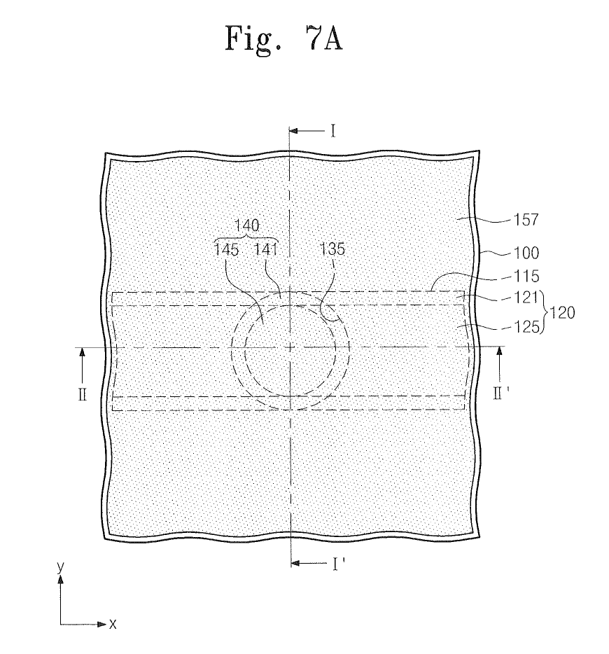

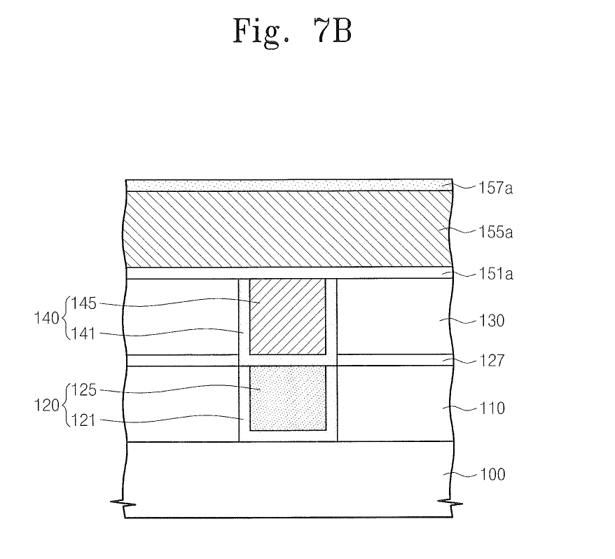

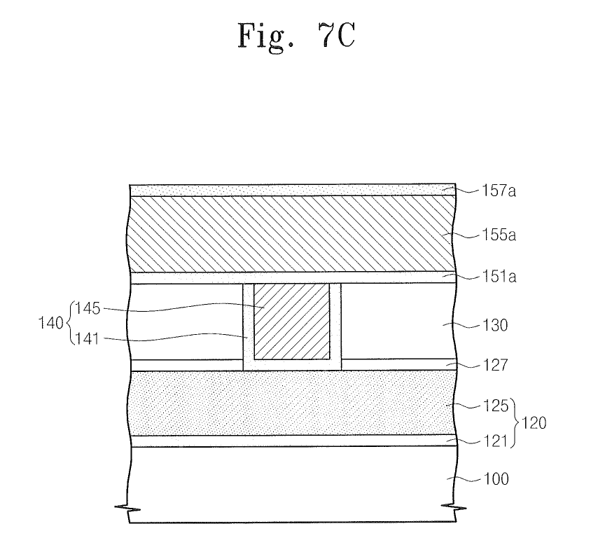

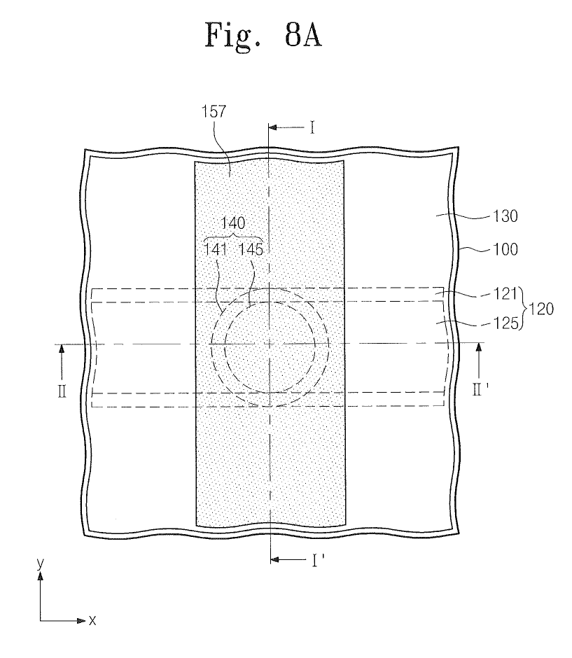

Referring to FIGS. 7A, 7B and 7C, a second barrier film 151a, a second conductive film 155a and an anti-reflection film 157a may be sequentially formed on the interlayer dielectric film 130. The second barrier film 151a and the second conductive film 155a may be formed by at least one of a chemical vapor deposition (CVD) process, a physical vapor deposition (PVD) process and an atomic layer deposition (ALD) process. The second barrier film 151a may include a metal nitride (e.g., titanium nitride, tungsten nitride or tantalum nitride) or a transition metal (e.g., titanium, tantalum, etc.). The second conductive film 155a may include at least one selected from a doped semiconductor (e.g., doped silicon), a metal (e.g., tungsten, aluminum, copper, etc.) and a conductive metal-semiconductor compound (e.g., a metal silicide).

The anti-reflection film 157a may be formed by a chemical vapor deposition (CVD) process using a source gas including a metal element, a carbon element and a nitrogen element. The source gas may include a first reaction gas and a second reaction gas. According to an embodiment, the first reaction gas may include a carbon element and a metal element, and the second reaction gas may include a nitrogen element. According to another embodiment, the first reaction gas may include a metal element, and the second reaction gas may include a carbon element and a nitrogen element. According to still another embodiment, the first reaction gas may include a carbon element and a metal element, and the second reaction gas may include a carbon element and a nitrogen element. Also, the first reaction gas may include a carbon element, and the second reaction gas may include a metal element and a nitrogen element.

The anti-reflection film 157a may include a compound including a metal, carbon and nitrogen. For example, the metal included in the compound may be titanium. According to an embodiment, a carbon content of the compound included in the anti-reflection film 157a may be 5-40 atomic %.

According to an embodiment, the density of the compound included in the anti-reflection film 157a may be lower than the density of PVD-metal nitride, e.g., that forms the second barrier film 151a. For example, the metal included in the compound may be titanium, and the PVD-metal nitride may be titanium nitride. The density, here, is expressed as mass per unit volume; and the compound included in the anti-reflection pattern 157 may have a higher porosity than the PVD-metal nitride.

According to an embodiment, the compound included anti-reflection film 157a may optionally include oxygen. For example, the compound may be titanium-carbon-nitride (TiCN) or titanium-carbon-oxygen-nitride (TiCON).

According to an embodiment, the diffusion coefficient of a mobile element in the anti-reflection film 157a may be greater than the diffusion coefficient of the mobile element in the capping film 127. Also, the diffusion coefficient of the mobile element in the compound included in the anti-reflection film 157a may be greater than the diffusion coefficient of the mobile element in PVD-metal nitride. The mobile element may include an element that may freely move in a film. For example, the mobile element may be hydrogen.

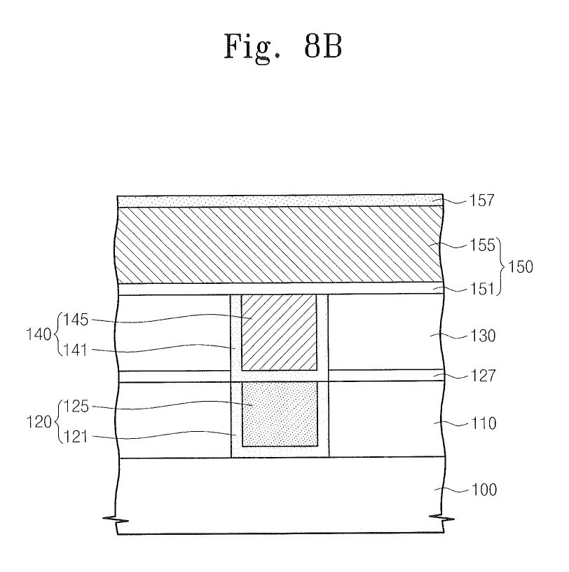

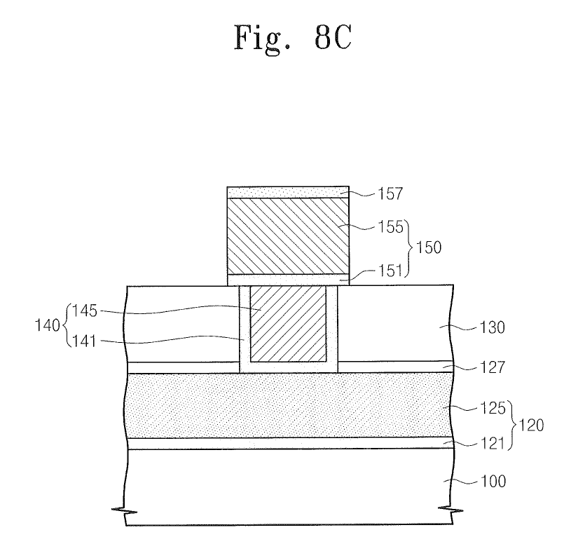

Referring to FIGS. 8A, 8B and 8C, a second barrier pattern 151, a second conductive line and an anti-reflection pattern 157 that are sequentially stacked may be formed by sequentially patterning the anti-reflection film 157a, the second conductive film 155a and the second barrier film 151a. The second barrier pattern 151 and the second conductive line 155 may be included in an upper interconnection 150. The upper interconnection 150 may be formed in a line shape extending in a second direction crossing the first direction.

The second barrier pattern 151, the second conductive line 155 and the anti-reflection pattern 157 may be formed by forming a photosensitive mask on the anti-reflection film 157a using a photosensitive process and etching the anti-reflection film 157a, the second conductive film 155a and the second barrier film 151a using the photosensitive mask as an etching mask. According to an embodiment, the second barrier pattern 151, the second conductive line 155 and the anti-reflection pattern 157 may be formed by one dry etching process being performed in one chamber.

According to an embodiment, the photosensitive mask may be removed by a process using oxygen after the second barrier pattern 151, the second conductive line 155 and the anti-reflection pattern 157 are formed.

As illustrated in FIGS. 1A, 1B and 1C, a protective film covering the upper interconnection 150 and the anti-reflection pattern 157 may be formed on the interlayer dielectric film 130. The protective film 130 may be formed by at least one of a chemical vapor deposition (CVD) process, a physical vapor deposition (PVD) process and an atomic layer deposition (ALD) process. The interlayer dielectric film 130 may include at least one of an oxide, a nitride and an oxynitride.

In an embodiment of the semiconductor device, described above, the anti-reflection pattern 157 disposed on the upper interconnection 150 may be formed of a compound including a metal, carbon and nitrogen. The compound included in the anti-reflection pattern 157 may be a porous material. Accordingly, in a process for forming a semiconductor device, a mobile element that passed through components constituting a semiconductor device may be easily emitted to the outside through the anti-reflection pattern o57.

Also, the diffusion coefficient of a mobile element in the anti-reflection pattern 157 may be greater than the diffusion coefficient of the mobile element in the capping film 127. In the case that mobile elements existing in components constituting a semiconductor device are prevented from emitting to the outside by the capping film 127, the mobile elements diffuse through the contact plug 140 and the upper interconnection 150 and are then easily emitted to the outside of the semiconductor device through the anti-reflection pattern 157. Thus, the problems that may be caused by the mobile elements in the semiconductor device may be minimized, and a semiconductor device having improved reliability may be produced.

The semiconductor devices disclosed in the embodiments described above may be embodied by various types of packages. For example, semiconductor devices in accordance with embodiments of the inventive concept may be packaged by various types of packages such as package on package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP) and mounted.

A package on which a semiconductor device in accordance with embodiments of the inventive concept is mounted may further include a semiconductor device (e.g., a controller and/or a logic device) performing different functions.

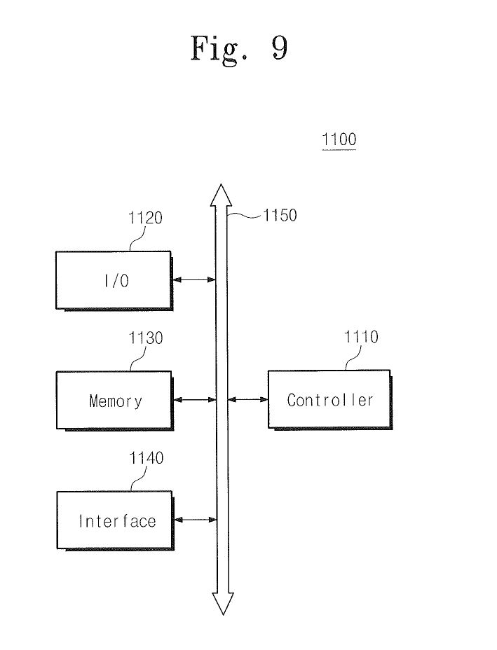

FIG. 9 is a block diagram illustrating an example of an electronic system including a semiconductor device in accordance with exemplary embodiments of the inventive concept.

Referring to FIG. 9, an electronic system 1100 in accordance with an embodiment of the inventive concept may include a controller 1110, an input/output device 1120, a memory device 1130, an interface 1140 and a bus 1150. The controller 1110, the input/output device 1120, the memory device 1130 and the interface 1140 may be connected to one another by the bus 1150. The bus 1150 may correspond to a path through which data move.

The controller 1110 may include at least one of a micro processor, a digital signal processor, a microcontroller and a logic device having a function similar to the micro processor, the digital signal processor and the microcontroller. In the case that the semiconductor devices disclosed in the embodiments described above are embodied by a logic device, the controller 1110 may include the semiconductor devices in accordance with the embodiments described above. The input/output device 1120 may include a keypad, a keyboard and a display device. The memory device 1130 may store data and/or a command. The memory device 1130 may include at least one of the semiconductor devices in accordance with the embodiments described above. The memory device 1130 may further include another type of semiconductor memory device (e.g., a DRAM device and/or a SRAM device). The interface 1140 may perform a function transmitting data to a communication network or receiving data from a communication network. The interface 1140 may be a wireline (wired) type and or a wireless type. The interface 1140 may include an antenna or a wireline/wireless transceiver. Although not illustrated in the drawing, the electronic system 1100 may further include a high-speed DRAM device and/or a SRAM device as an operation memory device to improve an operation of the controller 1110.

The electronic system 1100 may be incorporated into a personal digital assistant (PDA), a portable computer, a web tablet, a wireless phone, a mobile phone, a digital music player, a memory card or all the devices that can transmit and/or receive data in a wireless environment.

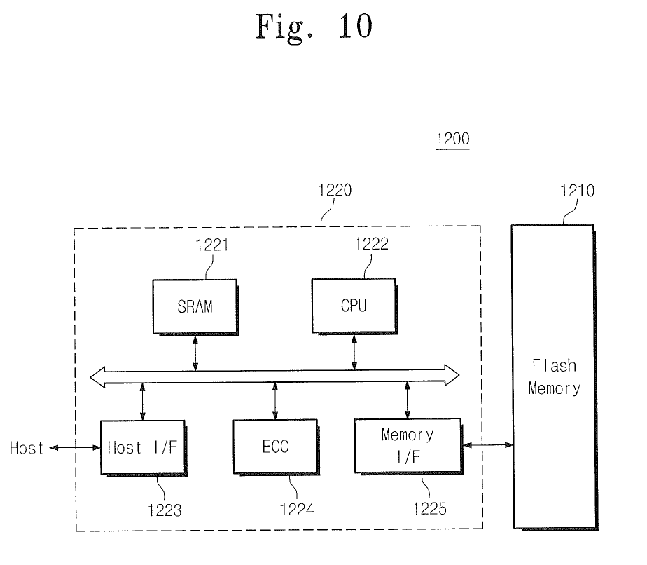

FIG. 10 is a block diagram illustrating an example of a memory card including a semiconductor device in accordance with exemplary embodiments of the inventive concept.

Referring to FIG. 10, a memory card 1200 in accordance with an embodiment of the inventive concept includes a memory device 1210. The memory device 1210 may include at least one of the semiconductor devices of the embodiments described above. Also, the memory device 1210 may further include another type of semiconductor device (e.g., a DRAM device and/or a SRAM device). The memory card 1200 may include a memory controller 1220 controlling a data exchange between a host and the memory device 1210.

The memory controller 1220 may include a processing unit 1222 controlling the whole operation of the memory card. Also, the memory controller 1220 may include a SRAM 1221 used as an operation memory of the processing unit 1222. In addition, the memory controller 1220 may further include a host interface 1223 and a memory interface 1225. The host interface 1223 may include a data exchange protocol between the memory card 1200 and a host. The memory interface 1225 may connect the memory controller 1220 and the memory device 1210. Further, the memory controller 1220 may further include an error correction code 1224. The error correction code 1224 can detect and correct data read out from the memory device 1210. Although not illustrated in the drawing, the memory card 1200 may further include a ROM device storing code data for interfacing with the host. The memory card 1200 may be used as a portable data storage card. The memory card 1200 may be embodied as a solid state disk (SSD) that can replace a hard disk of computer system.

According to the semiconductor device described above, an anti-reflection pattern disposed on an interconnection may be formed of a compound including metal, carbon and nitrogen. Accordingly, in a process for forming a semiconductor device, a mobile element that passed through components constituting a semiconductor device may be easily emitted to the outside through the anti-reflection pattern 157. Consequently, problems that may be caused by the mobile elements in the semiconductor device may be minimized, and a semiconductor device having improved reliability may be produced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

1. A semiconductor device comprising:
a substrate;
an upper interconnection on the substrate; and
an anti-reflection pattern disposed on the upper interconnection, wherein the anti-reflection pattern comprises a compound including a metal, carbon and nitrogen.

2. The semiconductor device of claim 1, wherein the compound included in the anti-reflection pattern has a carbon content of 5-40 atomic %.

3. The semiconductor device of claim 1, wherein the compound included in the anti-reflection pattern further comprises oxygen.

4. The semiconductor device of claim 1, wherein the upper interconnection and the anti-reflection pattern are directly in contact with each other.

5. The semiconductor device of claim 1, further comprising:
a mold dielectric film and an interlayer dielectric film that are sequentially stacked between the substrate and the upper interconnection;
a lower interconnection in the mold dielectric film;
a capping film between the lower interconnection and the interlayer dielectric film; and
a contact plug penetrating the interlayer dielectric film and the capping film between the upper interconnection and the lower interconnection and electrically connecting the upper interconnection and the lower interconnection.

6. The semiconductor device of claim 5, wherein the capping film comprises a nitride.

7. The semiconductor device of claim 5, wherein a mobile element in the semiconductor device has a diffusion coefficient in the compound included in the anti-reflection pattern that is greater than the diffusion coefficient of the mobile element in the capping film.

8. The semiconductor device of claim 1, wherein a mobile element in the semiconductor device has a diffusion coefficient in the compound included in the anti-reflection pattern that is greater than the diffusion coefficient of the mobile element in PVD-metal nitride.

9. The semiconductor device of claim 1, wherein the compound included in the anti-reflection pattern is selected from at least one of titanium carbon nitride and titanium carbon oxygen nitride.

10. The semiconductor device of claim 1, wherein the compound included in the anti-reflection pattern has a density lower than the density of PVD-metal nitride.

11. The semiconductor device of claim 1, wherein the upper interconnection comprises:
an electrically conductive line; and
a barrier pattern lining the electrically conductive line.

12. The semiconductor device of claim 11, wherein the electrically conductive line comprises at least one of a doped semiconductor, a metal, and a conductive metal-semiconductor compound, and wherein the barrier pattern comprises at least one of a metal nitride and a transition metal.

13.-17. (canceled)

18. A semiconductor device comprising:
a substrate;
a first layer on the substrate, the first layer including a mold dielectric film that defines a trench and a lower interconnection mounted in the trench, wherein the lower interconnection includes a first electrically conductive line and a first barrier pattern between the first electrically conductive line and both the mold dielectric film and the substrate;
a second layer on the first layer on an opposite side of the first layer from the substrate, the second layer including (a) a capping film on the lower interconnection, (b) an interlayer dielectric film on the capping film, wherein the interlayer dielectric film defines a trench, and (c) a contact plug in the trench and on the lower interconnection, wherein the contact plug includes a contact conductive pattern and a contact barrier pattern between the contact conductive pattern and both the interlayer dielectric film and the lower interconnection;
a third layer on the second layer on an opposite side of the second layer from the first layer, the third layer including an upper interconnection including a second electrically conductive line and a second barrier pattern between the second electrically conductive line and the second layer; and
an anti-reflection pattern on the second electrically conductive line on an opposite side of the electrically conductive line from the second barrier pattern, wherein the anti-reflection pattern comprises a compound including a metal, carbon and nitrogen.

19. The semiconductor device of claim 18, wherein the capping film has a composition in which hydrogen has a diffusion coefficient that is lower than the diffusion coefficient of hydrogen in the anti-reflection pattern.

20. The semiconductor device of claim 18, wherein:
the substrate comprises at least one of silicon and germanium;
the mold dielectric film and the interlayer dielectric film comprise at least one selected from an oxide, a nitride and an oxynitride;
the first and second electrically conductive lines as well as the contact conductive pattern comprise at least one selected from a doped semiconductor, a metal and a conductive metal-semiconductor compound;
the first and second barrier patterns as well as the contact barrier pattern comprise at least one selected from a metal nitride and a transition metal; and
the capping film comprises a nitride.
